(19) United States
(12) Patent Application Publication
(10) Pub. No.: US 2023/0011185 A1
(43) Pub. Date: Jan. 12, 2023

(54) LAMINATE, METHOD FOR MANUFACTURING LAMINATE, AND METHOD FOR MANUFACTURING SEMICONDUCTOR SUBSTRATE

(71) Applicant: TOKYO OHKA KOGYO CO., LTD., Kawasaki-shi (JP)

(72) Inventor: Keisuke KUBO, Kawasaki-shi (JP)

(21) Appl. No.: 17/905,244

(22) PCT Filed: Mar. 1, 2021
(86) PCT No.: PCT/JP2021/007776

§ 371 Date: Aug. 29, 2022

(30) Foreign Application Priority Data
Mar. 27, 2020 (JP) 2020-058444

(51) Int. Cl. H01L 21/225; H01L 21/02; H01L 21/22

(52) U.S. Cl. CPC H01L 21/2258; H01L 21/02126; H01L 21/2225; H01L 21/02282

(57) ABSTRACT

A laminate that can be used for diffusing an impurity diffusion component into a semiconductor substrate and manufactured by a method with good film formability, and which allows sufficient diffusion of the impurity diffusion component; a method for manufacturing the laminate; and a method for manufacturing a semiconductor substrate using the laminate. The laminate includes a diffusion-undergoing semiconductor substrate, an amine compound layer, and an impurity diffusion component layer, the amine compound layer is in contact with one main surface of the diffusion-undergoing semiconductor substrate, the impurity diffusion component layer is in contact with a main surface of the amine compound layer, the main surface is not in contact with the diffusion-undergoing semiconductor substrate, and the amine compound layer includes an amine compound including two or more nitrogen atoms and having an amino group constituted by at least one of the two or more nitrogen atoms; and/or an amine compound residue having one or more amino groups and bonding to the main surface via a covalent bond.

### TECHNICAL FIELD

This invention relates to a laminate that is used for diffusion of an impurity diffusion component into a semiconductor substrate, a method for manufacturing the laminate, and a method for manufacturing the semiconductor substrate using the laminate.

### BACKGROUND ART

Semiconductor substrates that are used for semiconductor elements such as a transistor, a diode, and a solar battery have been manufactured by diffusing, into a semiconductor substrate, an impurity diffusion component such as phosphorus and boron. A method of diffusing an impurity diffusion component into a semiconductor substrate can be exemplified by a method of applying an impurity diffusing agent composition containing an impurity diffusion component on a diffusion-undergoing semiconductor substrate. For example, as a method for doping silicon, a method for diffusing impurities (phosphorus) by applying a solution containing phosphoric acid on a surface of a silicon substrate has been disclosed (e.g. see Patent Document 1).

Patent Document 1: Japanese Unexamined Patent Application (Translation of PCT Application), Publication No. 2011-519477

### DISCLOSURE OF THE INVENTION

### Problems to Be Solved by the Invention

However, in a case that a solution of a phosphorus compound such as phosphoric acid is applied on a substrate to diffuse impurities as described in Patent Document 1, there is a problem of poor film formability. Also, it is possible to diffuse impurities (boron) by applying a solution of a boron compound such as boric acid, but there is, in addition to a problem of film formability, a problem that the boron compound tends to diffuse to the outside from the time of film formation to make it difficult to sufficiently diffuse the impurities. In view of the above circumstances, manufacture of semiconductor substrates on which an impurity diffusion component is diffused requires manufacturability by a method with a good film formability, and sufficient diffusibility of the impurity diffusion component.

The present invention has been made in view of the foregoing problems, and an object the present invention is to provide: a laminate that can be used for diffusing an impurity diffusion component into a semiconductor substrate and manufactured by a method with good film formability, and allows sufficient diffusion of the impurity diffusion component; a method for manufacturing the laminate; and a method for manufacturing a semiconductor substrate using the laminate.

### Means for Solving the Problems

The present inventors have found that the above problems can be solved by a laminate including a diffusion-undergoing semiconductor substrate, an amine compound layer, and an impurity diffusion component layer, in which the amine compound layer is in contact with one main surface of the diffusion-undergoing semiconductor substrate, the impurity diffusion component layer is in contact with a main surface of the amine compound layer, the main surface being not in contact with the diffusion-undergoing semiconductor substrate, and the amine compound layer includes an amine compound (B1) including two or more nitrogen atoms and having an amino group constituted by at least one of the two or more nitrogen atoms, and/or an amine compound residue (B2) having one or more amino groups and binding to the main surface via a covalent bond. Thereby the present inventors have completed the present invention. More specifically, the present invention provides the followings.

A first aspect of the present invention is a laminate that is used for diffusing an impurity diffusion component (A) into a semiconductor substrate, in which the laminate includes: a diffusion-undergoing semiconductor substrate; an amine compound layer; and an impurity diffusion component layer,
the amine compound layer is in contact with one main surface of the diffusion-undergoing semiconductor substrate, the impurity diffusion component layer is in contact with a main surface of the amine compound layer, the amine surface being not in contact with the diffusion-undergoing semiconductor substrate, and
the amine compound layer includes: an amine compound (B1) including two or more nitrogen atoms and having an amino group constituted by at least one of the two or more nitrogen atoms; and/or an amine compound residue (B2) having one or more amino groups and binding to the main surface via a covalent bond.

A second aspect of the present invention is a method for manufacturing the laminate according to the first aspect, the method including:
an amine compound-containing composition applying step for applying, on the diffusion-undergoing semiconductor substrate, an amine compound-containing composition including the amine compound (B1) or a reactive amine compound that provides the amine compound residue (B2); and
an impurity diffusion component-containing composition applying step for applying an impurity diffusion component-containing composition including the impurity diffusion component (A) after the amine compound-containing composition applying step.

A third aspect of the present invention is a method for manufacturing a semiconductor substrate, the method including a diffusion step for diffusing the impurity diffusion component (A) into the diffusion-undergoing semiconductor substrate by heating the laminate according to the first aspect.

### Effects of the Invention

According to the present invention, it is possible to provide: a laminate that can be used for diffusing an impurity diffusion component into a semiconductor substrate and manufactured by a method with good film formability, and allows sufficient diffusion of the impurity diffusion component; a method for manufacturing the laminate; and a method for manufacturing a semiconductor substrate using the laminate.

### BRIEF DESCRIPTION OF THE DRAWINGS

FIG. 1 is a schematic drawing illustrating a structural example of a laminate; and

FIG. 2 is a schematic drawing illustrating an example of a method for manufacturing a semiconductor substrate using the laminate.

### PREFERRED MODE FOR CARRYING OUT THE INVENTION

### Laminate, and Method for Manufacturing Laminate

The laminate according to the present invention is a laminate that is used for diffusing an impurity diffusion component (A) into a semiconductor substrate. The laminate includes a diffusion-undergoing semiconductor substrate, an amine compound layer, and an impurity diffusion component layer. The amine compound layer is in contact with one main surface of the diffusion-undergoing semiconductor substrate. The impurity diffusion component layer is in contact with a main surface of the amine compound layer, the main surface being not in contact with the diffusion-undergoing semiconductor substrate. The amine compound layer includes an amine compound (B1) including two or more nitrogen atoms and having an amino group constituted by at least one of the two or more nitrogen atoms, and/or an amine compound residue (B2) having one or more amino groups and binding to the main surface via a covalent bond.

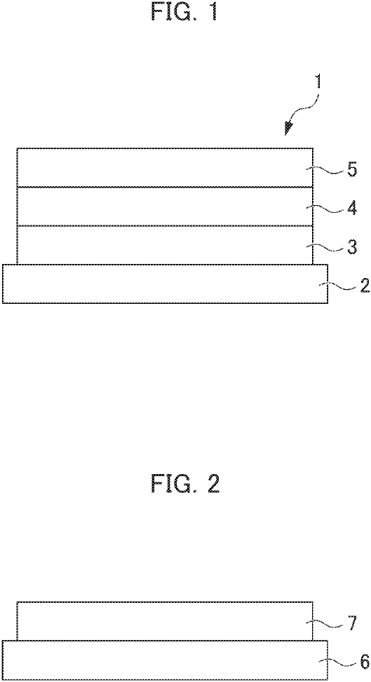

The laminate will be explained with reference to FIG. 1. FIG. 1 is a schematic drawing illustrating a structural example of the laminate. As illustrated in FIG. 1, a laminate 1 includes a diffusion-undergoing semiconductor substrate 2, an amine compound layer 3 in contact with an upper main surface of the diffusion-undergoing semiconductor substrate 2, and an impurity diffusion component layer 4 in contact with a main surface of the amine compound layer 3, not in contact with the diffusion-undergoing semiconductor substrate 2. FIG. 1 illustrates a laminate that further has a second amine compound layer 5 in contact with a main surface of the impurity diffusion component layer 4, not in contact with the amine compound layer 3, in which the second amine compound layer 5 is a topmost surface layer of the laminate 1. However, the laminate 1 only needs to have the amine compound layer 3 and the impurity diffusion component layer 4, and need not have the second amine compound layer 5.

### DiffusionUndergoing Semiconductor Substrate

The diffusion-undergoing semiconductor substrate 2 is a target into which the impurity diffusion component (A) is diffused. As the diffusion-undergoing semiconductor substrate 2, various substrates conventionally used for diffusing an impurity diffusion component can be used without any particular restriction. Typically, a silicon substrate is used as the diffusion-undergoing semiconductor substrate 2. The silicon substrate is selected as appropriate from an n-type silicon substrate and a p-type silicon substrate depending on a type of the impurity diffusion component (A). Many of semiconductor substrates such as silicon substrates include a natural oxide film formed by natural oxidation of the surface. For example, many of silicon substrates include a natural oxide film made mainly of SiO₂. Thus, a semiconductor substrate in which a natural oxide film has been removed from the surface of the semiconductor substrate using a hydrofluoric acid aqueous solution or the like may be used as the diffusion-undergoing semiconductor substrate 2.

The diffusion-undergoing semiconductor substrate 2 may have a three-dimensional structure including a convex portion and a concave portion on the main surface where the amine compound layer 3 is provided. The three-dimensional structure having the convex and concave portions can be exemplified by a nanoscale fine pattern. A shape of the pattern is not particularly limited, but typically includes a straight or curved line or groove shape with a rectangular cross-sectional shape, and a hole shape.

### Amine Compound Layer in Contact with Upper Main Surface of Diffusion-Undergoing Semiconductor Substrate

The amine compound layer 3 in contact with the upper main surface of the diffusion-undergoing semiconductor substrate 2 includes an amine compound (B1), and/or an amine compound residue (B2).

The amine compound (B1) includes two or more nitrogen atoms and has an amino group constituted by at least one of the two or more nitrogen atoms. The amino group may be any of a primary amino group, a secondary amino group, and a tertiary amino group. The amine compound (B1) is preferably a low molecular weight compound e.g. a compound having a molecular weight of 500 or less, more preferably a compound having a molecular weight of 400 or less, even more preferably a compound having a molecular weight of 300 or less. The amine compound (B1) may be a linear or branched aliphatic amine compound or may be an aliphatic amine compound having a cyclic skeleton. Since the desired effect produced by use of the amine compound (B1) is easily obtained, the amine compound (B1) is preferably a linear or branched aliphatic amine compound. The amine compound (B1) may include a carbon-carbon unsaturated bond. In terms of the stability of the amine compound layer, and the like, the amine compound (B1) preferably does not include a carbon-carbon unsaturated bond.

The amine compound (B1) can be exemplified by an amine compound represented by formula (B1-1) below. R^{b1}R^{b2}N— (—R^{b3}—NR^{b4}—) ₘ—R^{b5} ... (B1-1)

In formula (B1-1) , R^{b1}, R^{b2}, R^{b4}, and R^{b5} each independently represent hydrogen atom, an alkyl group having 1 or more and 6 or less carbon atoms, or a hydroxyalkyl group having 1 or more and 6 or less carbon atoms. R^{b3} represents an alkylene group having 1 or more and 6 or less carbon atoms. Here, m represents an integer of 1 or more and 5 or less, and m preferably represents an integer of 1 or more and 3 or less. When m represents an integer of 2 or more and 5 or less, a plurality of R^{b3}s may be identical or different, and a plurality of R^{b4}s may be identical or different. In formula (B1-1), any two groups selected from a group consisting of R^{b1}, R^{b2}, R^{b4}, and R^{b5} may be bound to form a ring. The amine compound represented by formula (B1-1) may include two rings.

The number of carbon atoms in the alkyl group serving as R^{b1}, R^{b2}, R^{b4}, and R^{b5} is 1 or more and 6 or less, and is preferably 1 or more and 4 or less. Specific examples of the alkyl group serving as R^{b1}, R^{b2}, R^{b4}, and R^{b5} include a methyl group, an ethyl group, an n-propyl group, an isopropyl group, an n-butyl group, an isobutyl group, a sec-butyl group, a tert-butyl group, an n-pentyl group, an n-hexyl group, and the like. Among them, a methyl group, an ethyl group, an n-propyl group, an isopropyl group, an n-butyl group, an isobutyl group, a sec-butyl group, and a tert-butyl group are preferable.

The number of carbon atoms in the hydroxyalkyl group serving as R^{b1}, R^{b2}, R^{b4}, and R^{b5} is 1 or more and 6 or less, and is preferably 1 or more and 4 or less. Specific examples of the hydroxyalkyl group serving as R^{b1}, R^{b2}, R^{b4}, and R^{b5} include a hydroxymethyl group (methylol group), a 2-hydroxyethyl group, a 3-hydroxy-n-propyl group, a 4-hydroxy-n-butyl group, a 5-hydroxy-n-pentyl group, a 6-hydroxy-n-hexyl group, and the like. Among them, a 2-hydroxyethyl group and a 3-hydroxy-n-propyl group are preferable.

The number of carbon atoms in the alkylene group serving as R^{b3} is 1 or more and 6 or less, and is preferably 1 or more and 4 or less. Specific examples of the alkylene group serving as R^{b3} include a methylene group, an ethane-1,2-diyl group, an ethane-1,1-diyl group, a propane-1,3-diyl group, a propane-1,2-diyl group, a propane-1,1-diyl group, a butane-1,4-diyl group, a pentane-1,5-diyl group, a hexane-1,6-diyl group, and the like. Among them, a methylene group, an ethane-1,2-diyl group, and a propane-1,3-diyl group are preferable.

Specific preferred examples of the amine compound (B1) include: alkanediamines such as ethylenediamine, 1,3-propanediamine, and 1,4-butanediamine; N-alkylalkanediamines such as N-methylethylenediamine, N-ethylethylenediamine, N-n-propylethylenediamine, N-isopropylethylenediamine, N-n-butylethylenediamine, N-isobutylethylenediamine, N-sec-butylethylenediamine, N-tert-butylethylenediamine, N-methyl-1,3-propanediamine, N-ethyl-1,3-propanediamine, N-n-propyl-1,3-propanediamine, N-isopropyl-1,3-propanediamine, N-n-butyl-1,3-propanediamine, N-isobutyl-1,3-propanediamine, N-sec-butyl-1,3-propanediamine, and N-tert-butyl-1,3-propanediamine; N,N-dialkylalkanediamines such as N,N-dimethylethylenediamine, N,N-diethylethylenediamine, N,N-di-n-propylethylenediamine, N,N-diisopropylethylenediamine, N,N-di-n-butylethylenediamine, N,N-diisobutylethylenediamine, N,N-di-sec-butylethylenediamine, N,N-di-tert-butylethylenediamine, N,N-dimethyl-1,3-propanediamine, N,N-diethyl-1,3-propanediamine, N,N-di-n-propyl-1,3-propanediamine, N,N-diisopropyl-1,3-propanediamine, N,N-di-n-butyl-1,3-propanediamine, N,N-diisobutyl-1,3-propanediamine, N,N-di-sec-butyl-1,3-propanediamine, and N,N-di-tert-butyl-1,3-propanediamine; N,N′-dialkylalkanediamines such as N,N′-dimethylethylenediamine, N,N′-diethylethylenediamine, N,N′-di-n-propylethylenediamine, N,N′-diisopropylethylenediamine, N,N′-di-n-butylethylenediamine, N,N′-diisobutylethylenediamine, N,N′-di-sec-butylethylenediamine, N,N′-di-tert-butylethylenediamine, N,N′-dimethyl-1,3-propanediamine, N,N′-diethyl-1,3-propanediamine, N,N′-di-n-propyl-1,3-propanediamine, N,N′-diisopropyl-1,3-propanediamine, N,N′-di-n-butyl-1,3-propanediamine, N,N′-diisobutyl-1,3-propanediamine, N,N′-di-sec-butyl-1,3-propanediamine, and N,N′-di-tert-butyl-1,3-propanediamine; N,N,N′,N′-tetraalkylalkanediamine such as N,N,N′,N′-tetramethylethylenediamine, N,N,N′,N′-tetraethylethylenediamine, N,N,N′,N′-tetrapropylethylenediamine, and N,N,N′,N′-tetrabutylethylenediamine; aliphatic amines having 3 or more nitrogen atoms such as diethylenetriamine, triethylenetetramine, tetraethylenepentamine, 3,3-diaminodipropylamine, N,N′-bis(3-aminopropyl) ethylenediamine, N,N′-bis(3-aminopropyl)-1,3-propanediamine, tris(2-aminoethyl)amine, and tris(3-aminopropyl)amine, N-(2-aminoethyl)piperazine, and N-(3-aminopropyl)piperazine; hydroxyalkylamines such as N-(2-aminoethyl)ethanolamine, N,N-bis(2-aminoethyl)ethanolamine, N,N-bis(2-hydroxyethyl)ethylenediamine, N-(3-aminopropyl)ethanolamine, N,N-bis(3-aminopropyl)ethanolamine, and N,N-bis(2-hydroxyethyl)-1,3-propanediamine; and aliphatic diamines having a cyclic skeleton, such as piperazine, N-methylpiperazine, and N-ethylpiperazine; and the like.

The number of carbon atoms in the amine compound (B1) is preferably 2 or more and 15 or less, more preferably 3 or more and 10 or less. The number of nitrogen atoms in the amine compound (B1) is 2 or more, and from the viewpoint of diffusion property, preferably 3 or more, more preferably 4 or more. It is particularly preferable that the amine compound (B1) includes an amine having four or more amino groups. The number of nitrogen atoms in the amine compound (B1) is preferably 12 or less, more preferably 8 or less, further preferably 6 or less.

The amine compound layer 3 may include the amine compound (B1) alone or in combination of two or more types.

The amine compound residue (B2) has one or more amino groups and binds to the main surface of the diffusion-undergoing semiconductor substrate 2 via a covalent bond. The amino group may be any of a primary amino group, a secondary amino group, and a tertiary amino group. The reactive amine compound is e.g. a linear or branched aliphatic amine compound. The amine compound residue (B2) is e.g. a residue of a reactive amine compound having one or more amino groups and a group that binds to the main surface of the diffusion-undergoing semiconductor substrate 2 via a covalent bond. A form of the covalent bond formed between the main surface of the diffusion-undergoing semiconductor substrate 2 and the amine compound residue is not particularly limited as long as the object of the present invention is not inhibited. Production of the covalent bond will be explained below by taking, as an example, a case that the diffusion-undergoing semiconductor substrate 2 is a silicon substrate. Suitable examples of the covalent bond production include 1) to 4) below:
1) production of an Si—C bond by a reaction of a carbon-carbon unsaturated bond with Si—H on the surface of the silicon substrate;
2) production of an Si—O—C bond by a reaction of a hydroxy group (C—OH) that binds to carbon atom with Si—H on the silicon substrate surface;
3) production of an Si—O—C bond by a reaction of an aldehyde group (—CHO) with Si—H on the silicon substrate surface; and
4) production of an Si—O—Si bond, an Si—O—Ti bond, or an Si—O—Al bond by a dehydration-condensation reaction of a silanol (Si—OH) group, a titanol (Ti—OH) group, or an aluminol (Al-OH) group with a hydroxy group on the surface of the silicon substrate.

Among the above reactions to produce a covalent bond, 4) is preferable because of availability of the reactive amine compound, excellent reactivity of the reactive amine compound, and the like. When the reaction 4) is performed, a silane coupling agent, a titanate coupling agent or an aluminate coupling agent, having an amino group, and a hydrolyzable group such as an alkoxy group and a halogen atom on Si atom, Ti atom, or Al atom can be used as the reactive amine compound. Among these coupling agents, the silane coupling agent is preferable because of availability and the like. In other words, an aminosilane coupling agent in which an aliphatic hydrocarbon group is substituted with an amino group is preferable as the reactive amine compound.

The aminosilane coupling agent can be exemplified by an aminosilane coupling agent represented by formula (B2—1) below.

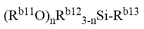

(R^{b11} represents a substituted or unsubstituted alkyl group having 1 or more and 3 or less carbon atoms, R^{b12} represents a substituted or unsubstituted alkyl group having 1 or more and 3 or less carbon atoms, and R^{b13} represents an alkyl group having an amino group in its chain and/or at its terminal, and n represents an integer of 1 or more and 3 or less.)

For R^{b11} and R^{b12}, examples of the substituent that may be included in the alkyl group include an alkoxy group having 1 or more and 6 or less carbon atoms, an alkenyloxy group having 2 or more and 6 or less carbon atoms, an aliphatic acyl group having 2 or more and 6 or less carbon atoms, a benzoyl group, a nitro group, a nitroso group, a hydroxy group, a cyano group, a sulfonic acid group, an amino group such as a primary amino group, a carboxy group, a hydroxy group, a mercapto group, a halogen atom, and the like. The number of the substituents included in R^{b11} and R^{b12} is not particularly limited as long as the object of the present invention is not inhibited. When R^{b11} and R^{b12} have substituents, the number of the substituents is preferably 3 or less, more preferably 1. When R^{b11} and R^{b12} have a plurality of substituents, the plurality of substituents may be identical or different.

Specific examples of the aminosilane coupling agent include 3-aminopropyltrimethoxysilane, 3-aminopropyltriethoxysilane, N-2-(aminoethyl)-3-aminopropyl methyldimethoxysilane, N-2-(aminoethyl)-3-aminopropyltrimethoxysilane, N-2-(aminoethyl)-3-aminopropyltriethoxysilane, 3-[2-(2-aminoethylaminoethylamino) propyl] trimethoxysilane, 3-[2-(2-aminoethylaminoethylamino) propyl] triethoxysilane, and the like. The aminosilane coupling agent may be used alone or in combination of a plurality of types. These preferred aminosilane coupling agents are represented by chemical formulas (a) to (g) below.

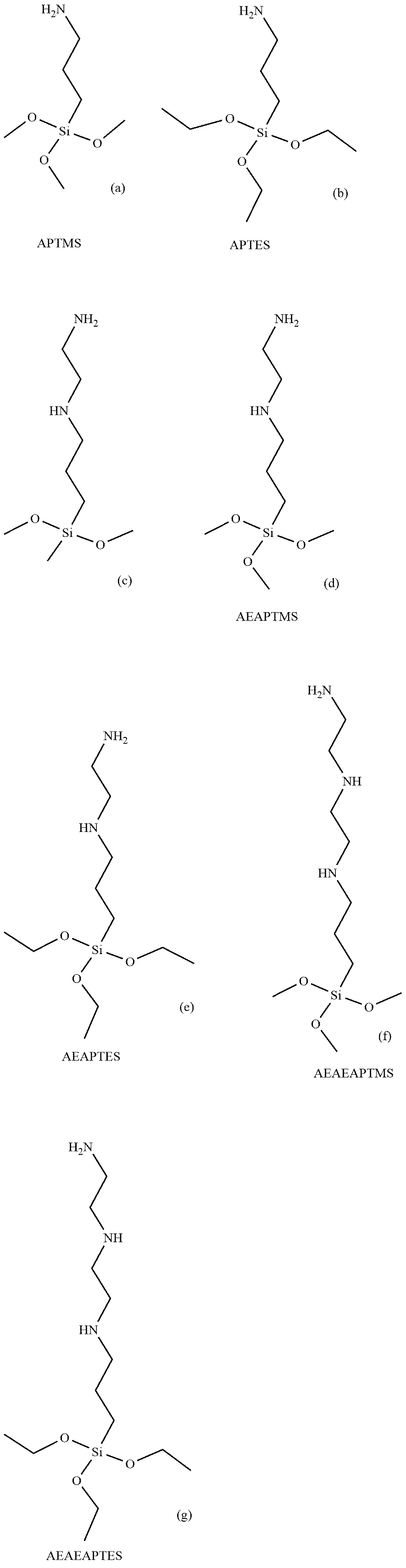

The amine compound layer 3 may include an amine compound residue (B2) alone or in combination of two or more types.

Contents of the amine compound (B1) and the amine compound residue (B2) in the amine compound layer 3 are not particularly limited as long as desired effects can be obtained by using the amine compound (B1) and the amine compound residue (B2).

### Impurity Diffusion Component Layer

The impurity diffusion component layer 4 includes the impurity diffusion component (A). The impurity diffusion component (A) is not particularly limited as long as the impurity diffusion component (A) is a component which is conventionally used for doping of a semiconductor substrate, and may be an n-type dopant or a p-type dopant. Examples of the n-type dopant include simple substances such as phosphorus, arsenic, and antimony, as well as compounds including these elements. Examples of the p-type dopant include simple substances such as boron, gallium, indium, and aluminum, as well as compounds including these elements.

As the impurity diffusion component (A), a phosphorus compound, a boron compound, or an arsenic compound is preferable because of availability and ease of handling. Examples of the phosphorus compound include phosphoric acid, phosphorous acid, diphosphorus acid, polyphosphoric acid, diphosphorus pentoxide, phosphite esters, phosphate esters, tris phosphite (trialkylsilyl), tris phosphate (trialkylsilyl), and the like. Examples of the boron compound include boric acid, metaboric acid, boronic acid, perboric acid, hypoboric acid, diboron trioxide, trialkyl borate, tetrahydroxydiborane, monoalkoxytrihydroxydiborane, dialkoxydihydroxydiborane, trialkoxymonohydroxydiborane, and tetra alkoxydiborane. Examples of the arsenic compound include arsenic acid and trialkyl arsenate.

As the phosphorus compound, phosphoric acid, phosphite esters, phosphate esters, tris phosphite (trialkylsilyl), and tris phosphate (trialkylsilyl) are preferable, among them, phosphoric acid, trimethyl phosphate, triethyl phosphate, trimethyl phosphite, triethyl phosphite, tris phosphate (trimethylsilyl), and tris phosphite (trimethylsilyl) are preferable, trimethyl phosphate, trimethyl phosphite, and tris phosphate (trimethylsilyl) are more preferable, and trimethyl phosphate is particularly preferable.

As the boron compound, boric acid, trimethoxyboron, triethoxyboron, tri-n-propoxyboron, triisopropoxyboron, tri-n-butoxyboron, trimethylboron, triethylboron, and tetrahydroxydiborane are preferable.

As the arsenic compound, arsenic acid, triethoxy arsenic, and tri-n-butoxy arsenic are preferable.

A content of the impurity diffusion component (A) in the impurity diffusion component layer 4 is not particularly limited.

The laminate 1 having the diffusion-undergoing semiconductor substrate 2, the amine compound layer 3 in contact with a main surface of the diffusion-undergoing semiconductor substrate 2, and the impurity diffusion component layer 4 in contact with a main surface of the amine compound layer 3, the main surface being not in contact with the diffusion-undergoing semiconductor substrate 2, can be heated (annealed) to allow sufficient diffusion of the impurity diffusion component (A) into the diffusion-undergoing semiconductor substrate 2. The reason why the impurity diffusion component (A) can be sufficiently diffused into the diffusion-undergoing semiconductor substrate 2 is not clear, but is assumed to be due to the following mechanism.

A hydroxy group on the surface of the diffusion-undergoing semiconductor substrate 2 such as a silicon substrate and nitrogen atoms of the amine compound (B1) included in the amine compound layer 3 form a hydrogen bond, or a reaction of the reactive amine compound that provides the amine compound residue (B2) with a functional group on the surface of the diffusion-undergoing semiconductor substrate 2 forms a covalent bond. Then, a nitrogen atom uninvolved in the bonding with the surface of the diffusion-undergoing semiconductor substrate 2 among the nitrogen atoms included in the amine compound (B1) and the amine compound residue (B2) binds with the impurity diffusion component (A) included in the impurity diffusion component layer 4 via a hydrogen bond. Thus, when the laminate 1 is heated to diffuse the impurity diffusion component (A) into the diffusion-undergoing semiconductor substrate 2, the impurity diffusion component (A) is prevented from diffusing to the outside due to sublimation or the like. Thereby, the impurity diffusion component (A) can be sufficiently diffused into the diffusion-undergoing semiconductor substrate 2. On the other hand, if the laminate 1 does not have the amine compound layer 3, the impurity diffusion component (A) tends to diffuse to the outside due to sublimation or the like during heating of the laminate 1 for diffusing the impurity diffusion component (A) into the diffusion-undergoing semiconductor substrate 2, and the impurity diffusion component (A) cannot be sufficiently diffused into the diffusion-undergoing semiconductor substrate 2. The laminate 1 illustrated in FIG. 1 further has a second amine compound layer 5 in contact with the main surface of the impurity diffusion component layer 4, not in contact with the amine compound layer 3, and it is assumed that the impurity diffusion component (A) included in the impurity diffusion component layer 4 binds with nitrogen atoms of the amine compound (B1) and amine compound residue (B2) included in the second amine compound layer 5 via hydrogen bond or the like.

In addition, as will be described below in detail, such a laminate 1 can be manufactured e.g. by applying an amine compound-containing composition including an amine compound (B1) or a reactive amine compound that provides an amine compound residue (B2) on the substrate, and then applying the impurity diffusion component-containing composition that contains the impurity diffusion component (A) thereon. According to this manufacturing method, the film formability is improved, and generation of foreign matters is suppressed.

Herein, there need not be a clear interface between the amine compound layer 3 and the impurity diffusion component layer 4. In this case, for example, analysis according to Parallel Angle Resolved X-ray Photoelectron Spectroscopy (PAR-XPS) or analysis according to Time-of-Flight Secondary Ion Mass Spectrometry (TOF-SIMS) makes it possible to observe the amine compound layer 3 on the surface of the diffusion-undergoing semiconductor substrate 2 and the impurity diffusion component layer 4 on the amine compound layer 3 on the opposite side of the diffusion-undergoing semiconductor substrate 2. For example, in detection intensity profiles of each component obtained by PAR-XPS analysis for the laminate 1, the amine compound layer 3 is a region where a detection intensity of the bond involving nitrogen atom derived from the amine compound (B1) or the reactive amine compound that provides the amine compound residue (B2) is stronger than that of the impurity diffusion component (A). In detection intensity profiles of each component obtained by PAR-XPS analysis for the laminate 1, the impurity diffusing compound layer 4 is a region where a detection intensity of the impurity diffusion component (A) is stronger than that of the bond involving nitrogen atom derived from the amine compound (B1) or the reactive amine compound that provides the amine compound residue (B2).

The laminate 1 may further have a second impurity diffusion component layer in contact with the main surface of the second amine compound layer 5, not in contact with the impurity diffusion component layer 4, and may further have the amine compound layers and the impurity diffusion component layers alternately.

### Method for Manufacturing Laminate

The method for manufacturing the laminate 1 is not particularly limited, but the laminate 1 can be manufactured e.g. by a laminate manufacturing method including an amine compound-containing composition applying step for applying, on the diffusion-undergoing semiconductor substrate 2, an amine compound-containing composition including the amine compound (B1) or the reactive amine compound that provides the amine compound residue (B2); and an impurity diffusion component-containing composition applying step for applying the impurity diffusion component-containing composition including the impurity diffusion component (A) after the amine compound-containing composition applying step.

### Amine Compound-Containing Composition Applying Step

In the amine compound-containing composition applying step, an amine compound-containing composition including the amine compound (B1) or the reactive amine compound that provides the amine compound residue (B2) is applied on the diffusion-undergoing semiconductor substrate 2.

The amine compound-containing composition normally includes an organic solvent (S) as a solvent so as to be able to form a coating film. A type of the organic solvent (S) is not particularly limited as long as the object of the present invention is not inhibited.

Preferably, when the amine compound-containing composition includes an aminosilane coupling agent as the reactive amine compound that provides the amine compound residue (B2), the amine compound-containing composition substantially does not include water. That the amine compound-containing composition substantially does not include water means that the amine compound-containing composition does not contain such an amount of water as to hydrolyze the aminosilane coupling agent and thus to prevent the acquisition of the desired effect produced by the addition thereof. However, even when the amine compound-containing composition includes an aminosilane coupling agent as the reactive amine compound that provides the amine compound residue (B2), a solvent for the amine compound-containing composition may contain water if the time between the production of the amine compound-containing composition and the application thereof is short.

Specific examples of the organic solvent (S) include: glycol monoethers such as ethylene glycol monomethyl ether, ethylene glycol monoethyl ether, ethylene glycol monopropyl ether, ethylene glycol monobutyl ether, propylene glycol monomethyl ether, propylene glycol monoethyl ether, propylene glycol monopropyl ether, propylene glycol monobutyl ether, diethylene glycol monomethyl ether, diethylene glycol monoethyl ether, diethylene glycol monopropyl ether, diethylene glycol monobutyl ether, diethylene glycol monophenyl ether, dipropylene glycol monomethyl ether, dipropylene glycol monoethyl ether, dipropylene glycol monopropyl ether, dipropylene glycol monobutyl ether, dipropylene glycol monophenyl ether, triethylene glycol monomethyl ether, triethylene glycol monoethyl ether, tripropylene glycol monomethyl ether, and tripropylene glycol monoethyl ether; monoethers such as diisopentyl ether, diisobutyl ether, benzyl methyl ether, benzyl ethyl ether, dioxane, tetrahydrofuran, anisole, perfluoro-2-butyltetrahydrofuran, and perfluorotetrahydrofuran; glycol chain diethers such as ethylene glycol dimethyl ether, ethylene glycol diethyl ether, ethylene glycol dipropyl ether, ethylene glycol dibutyl ether, propylene glycol dimethyl ether, propylene glycol diethyl ether, propylene glycol dipropyl ether, propylene glycol dibutyl ether, diethylene glycol dimethyl ether, diethylene glycol diethyl ether, diethylene glycol dipropyl ether, diethylene glycol dibutyl ether, dipropylene glycol dimethyl ether, dipropylene glycol diethyl ether, dipropylene glycol dipropyl ether, and dipropylene glycol dibutyl ether; cyclic diethers such as 1,4-dioxane; ketones such as 1-octanone, 2-octanone, 1-nonanone, 2-nonanone, acetone, 2-heptanone, 4-heptanone, 1-hexanone, 2-hexanone, 3-pentanone, diisobutylketone, cyclohexanone, methylcyclohexanone, phenylacetone, methylethylketone, methyl isobutyl ketone, ethyl isobutyl ketone, acetylacetone, acetonylacetone, ionone, diacetonyl alcohol, acetylcarbinol, acetophenone, methylnaphthylketone, and isophorone; esters such as methyl acetate, butyl acetate, ethyl acetate, isopropyl acetate, pentyl acetate, isopentyl acetate, methoxyethyl acetate, ethyl ethoxy acetate, ethylene glycol monomethyl ether acetate, ethylene glycol monoethyl ether acetate, ethylene glycol monopropyl ether acetate, ethylene glycol monobutyl ether acetate, ethylene glycol monophenyl ether acetate, propylene glycol monomethyl ether acetate, propylene glycol monoethyl ether acetate, propylene glycol monopropyl ether acetate, propylene glycol monobutyl ether acetate, propylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl-3-methoxypropionate, ethyl-3-methoxypropionate, ethyl-3-ethoxypropionate, propyl-3-methoxypropionate, isopropyl-3-methoxypropionate, propylene carbonate, and γ-butyrolactone; amide solvents free of active hydrogen atoms such as N-methyl-2-pyrrolidone, N,N-dimethylacetamide, N,N-dimethylformamide, hexamethylphosphoric triamide, and 1,3-dimethyl-2-imidazolidinone; sulfoxides such as dimethyl sulfoxide; aliphatic hydrocarbon solvents which may include halogens, such as pentane, hexane, octane, decane, 2,2,4-trimethylpentane, 2,2,3-trimethylhexane, perfluorohexane, perfluoroheptane, limonene, and pinene; aromatic hydrocarbon solvents such as benzene, toluene, xylene, ethylbenzene, propylbenzene, 1-methylpropylbenzene, 2-methylpropylbenzene, diethylbenzene, ethylmethylbenzene, trimethylbenzene, ethyldimethylbenzene, and dipropylbenzene; monohydric alcohols such as methanol, ethanol, n-propanol, isopropanol, butanol, isobutanol, 2-methoxyethanol, 2-ethoxyethanol, 3-methyl-3-methoxybutanol, hexanol, cyclohexanol, benzyl alcohol, and 2-phenoxyethanol; and glycols such as ethylene glycol, propylene glycol, diethylene glycol, and dipropylene glycol. Among them, when the amine compound-containing composition includes the amine compound (B1), the organic solvent (S) is preferably a glycol monoether such as propylene glycol monomethyl ether, an ester such as propylene glycol monomethyl ether acetate, or an alcohol solvent such as a monovalent alcohol. In the preferred examples of the organic solvent (S) described above, organic solvents including an ether bond and an ester bond are classified into esters. These organic solvents may be used alone or in combination of two or more types.

When the amine compound-containing composition includes an aminosilane coupling agent, the organic solvent (S) which does not have a functional group reacting with aminosilane coupling agent is preferably used. Examples of the functional group reacting with the aminosilane coupling agent include a hydroxy group, a carboxy group, an amino group, a halogen atom, and the like.

As preferred examples of the organic solvent which does not have a functional group reacting with the aminosilane coupling agent, among the specific examples of the organic solvent (S) described above, the organic solvents listed as the specific examples of monoethers, chain diethers, cyclic diethers, ketones, esters, amide solvents free of active hydrogen atoms, sulfoxides, aliphatic hydrocarbon solvents which may include halogens, and aromatic hydrocarbon solvents are mentioned.

The amine compound-containing composition may include various additives such as a surfactant, a defoamer, a pH adjuster, and a viscosity adjuster as long as the object of the present invention is not inhibited. In order to improve the coating or the film formation, the amine compound-containing composition may include a binder resin. As the binder resin, various resins can be used, and an acrylic resin is preferable.

Predetermined amounts of the components described above are uniformly mixed, and thus the amine compound-containing composition can be obtained.

Contents of the amine compound (B1) and the reactive amine compounds that provide the amine compound residue (B2) in the amine compound-containing composition are not particularly limited as long as desired effects can be obtained by using the amine compound (B1) and the reactive amine compounds that provide the amine compound residue (B2). The total mass of the amine compound (B1) and the reactive amine compound that provides the amine compound residue (B2) in the amine compound-containing composition is 0.01% by mass or more and 20% by mass or less, more preferably 0.02% by mass or more and 5% by mass or less, particularly preferably 0.03% by mass or more and 2% by mass or less. As the content of the amine compound (B1) or the reactive amine compound that provides the amine compound residue (B2) in the amine compound-containing composition increases, the impurity diffusion component (A) tends to diffuse into the diffusion-undergoing semiconductor substrate 2.

The method of applying the amine compound-containing composition is not particularly limited as long as the coating film having a desired film thickness can be formed. As the method of applying the amine compound-containing composition, a spin coat method, an immersion method, an inkjet method, and a spray method are preferable, and the spin coat method and the immersion method are particularly preferable.

After the application, drying treatment may be performed. The drying treatment makes it possible to remove the solvent. For drying treatment conditions, the heating temperature is e.g. 50° C. or higher and 250° C. or lower, preferably 80° C. or higher and 150° C. or lower. The heating time is preferably 5 seconds or longer and 5 minutes or shorter, more preferably 30 seconds or longer and 2 minutes or shorter.

The film thickness of the coating film formed from the amine compound-containing composition is not particularly limited. The film thickness of the amine compound-containing composition is preferably 0.1 nm or more and 30 nm or less, more preferably 0.5 nm or more and 10 nm or less, even more preferably 0.5 nm or more and 5 nm or less. The film thickness of the coating film is an average value of film thicknesses of five or more points measured with an ellipsometer.

### Impurity Diffusion Component-Containing Composition Applying Step

In the impurity diffusion component-containing composition applying step, the impurity diffusion component-containing composition containing the impurity diffusion component (A) is applied after the amine compound-containing composition applying step.

The impurity diffusion component-containing composition normally includes an organic solvent (S) as a solvent so as to be able to form a coating film. The type of the organic solvent (S) is not particularly limited as long as the object of the present invention is not inhibited. Specific examples of the organic solvent (S) are the same as those of the organic solvent (S) in the amine compound-containing composition.

The impurity diffusion component-containing composition may include various additives such as a surfactant, a defoamer, a pH adjuster, and a viscosity adjuster as long as the object of the present invention is not inhibited. In order to improve the coating or the film formation, the impurity diffusion component-containing composition may include a binder resin. As the binder resin, various resins can be used, and an acrylic resin is preferable. Preferably, the impurity diffusion component-containing composition does not contain the amine compound (B1) or the reactive amine compound that provides the amine compound residue (B2).

Predetermined amounts of the components described above are uniformly mixed, and thus the impurity diffusion component-containing composition can be obtained.

The content of the impurity diffusion component (A) in the impurity diffusion component-containing composition is not particularly limited. The content of the impurity diffusion component (A) in the impurity diffusion component-containing composition is preferably 0.01% by mass or more and 20% by mass or less, more preferably 0.02% by mass or more and 5% by mass or less, particularly preferably 0.03% by mass or more and 1% by mass or less.

A ratio of a number of moles of the impurity diffusion component (A) in the impurity diffusion component-containing composition to a number of moles of the amine compound (B1) in the amine compound-containing composition (number of moles of the impurity diffusion component (A) in the impurity diffusion component-containing composition/number of moles of the amine compound (B1) in the amine compound-containing composition) is preferably 0.1 or more and 10 or less, more preferably 0.2 or more and 8 or less, even more preferably 0.3 or more and 6 or less. In addition, a ratio of a number of moles of the impurity diffusion component (A) in the impurity diffusion component-containing composition to a number of moles of the reactive amine compound that provides the amine compound residue (B2) in the amine compound-containing composition (number of moles of the impurity diffusion component (A) in the impurity diffusion component-containing composition/number of moles of the reactive amine compound that provides the amine compound residue (B2) in the amine compound-containing composition) is preferably 0.1 or more and 35 or less, more preferably 0.2 or more and 30 or less, even more preferably 0.3 or more and 25 or less.

The method of applying the impurity diffusion component-containing composition is not particularly limited as long as a coating film having a desired film thickness can be formed. As the method of applying the impurity diffusion component-containing composition, a spin coat method, an inkjet method, and a spray method are preferable, and the spin coat method is particularly preferable.

After the application, drying treatment may be performed. The drying treatment makes it possible to remove the solvent. For drying treatment conditions, the heating temperature is e.g. 50° C. or higher and 250° C. or lower, preferably 80° C. or higher and 150° C. or lower. The heating time is preferably 5 seconds or longer and 5 minutes or shorter, more preferably 30 seconds or longer and 2 minutes or shorter.

The film thickness of the coating film formed from the impurity diffusion component-containing composition is not particularly limited. For example, a total film thickness of the amine compound layer 3 and the impurity diffusion component layer 4 formed on the main surface of the diffusion-undergoing semiconductor substrate 2 is preferably 0.5 nm or more and 30 nm or less, more preferably 1 nm or more and 20 nm or less. The film thickness is an average value of film thicknesses of five or more points measured with an ellipsometer.

A pre-diffusion heating processing for processing the semiconductor substrate under a temperature condition lower than a diffusion temperature (heating temperature in the diffusion step) for a predetermined time may be performed after the application of the impurity diffusion component-containing composition. The condition of the heating processing described above is preferably 450° C. or higher and lower than 700° C. for 5 seconds or longer and 1 minute or shorter. The pre-diffusion heating processing is preferably performed at a constant temperature.

When the semiconductor substrate is processed under the temperature condition lower than the diffusion temperature for a predetermined time, depending on the type of the impurity diffusion component (A), it is likely that the sublimation of the impurity diffusion component (A) is reduced and that the diffusion properties (such as in-plane uniformity and a resistance value) of the impurity diffusion component (A) can be enhanced. The performance of the pre-diffusion heating processing is effective particularly when the impurity diffusion component (A) is a boron compound. It can be considered that boron in the impurity diffusion component (A) is oxidized into borate glass and that thus boron is easily fixed as a film.

A temperature in the pre-diffusion heating processing is preferably within a range of 450° C. or higher and lower than 700° C., more preferably 500° C. or higher and 690° C. or lower, particularly preferably 500° C. or higher and 670° C. or lower.

In terms of a balance between the effect of enhancing the impurity diffusion property in the pre-diffusion heating processing and the efficiency of manufacturing of the semiconductor substrate, the heating processing time in the pre-diffusion heating processing is preferably 5 seconds or longer and 45 seconds or shorter, more preferably 10 seconds or longer and 30 seconds or shorter.

When the amine compound-containing composition applying step and the impurity diffusion component-containing composition applying step are performed in this order, the amine compound layer 3 and the impurity diffusion component layer 4 are formed in this order on the diffusion-undergoing semiconductor substrate 2 to form the laminate 1. As described in Examples below, this manufacturing method suppresses generation of foreign matters because of excellent film formability. When the laminate 1 also has the second amine compound layer 5, the amine compound layer 3, the impurity diffusion component layer 4, and the second amine compound layer 5 may be formed in this order on the diffusion-undergoing semiconductor substrate 2 by further performing the amine compound-containing composition applying step after the impurity diffusion component-containing composition applying step.

### Method for Manufacturing Semiconductor Substrate

The semiconductor substrate can be manufactured by heating the aforementioned laminate. That means, the method for manufacturing the semiconductor substrate includes a diffusion step for diffusing the impurity diffusion component (A) into the diffusion-undergoing semiconductor substrate by heating the laminate.

### Diffusion Step

In the diffusion step, the impurity diffusion component (A) in the impurity diffusion component layer 4 formed on the diffusion-undergoing semiconductor substrate 2 is diffused into the diffusion-undergoing semiconductor substrate 2. If the amine compound layer 3 formed on the diffusion-undergoing semiconductor substrate 2 also includes the impurity diffusion component (A), the impurity diffusion component (A) in the amine compound layer 3 may also be diffused into the diffusion-undergoing semiconductor substrate 2. A method of diffusing the impurity diffusion component (A) into the diffusion-undergoing semiconductor substrate 2 is not particularly limited as long as the impurity diffusion component (A) contained in the impurity diffusion component layer 4 is diffused by heating. In the specification of the present application, the “diffusion step” is defined as a step which is performed from the time when the temperature reaches a predetermined diffusion temperature until a diffusion time (holding time of the diffusion temperature) elapses.

As a typical method, a method of heating, in a heating furnace such as an electric furnace, the laminate is mentioned. In this case, a heating condition is not particularly limited as long as the impurity diffusion component (A) is diffused to a desired degree.

The heating for the diffusion of the impurity diffusion component (A) is performed, at a temperature which is preferably 700° C. or higher and 1400° C. or lower, more preferably 700° C. or higher and lower than 1200° C., preferably for 1 second or longer and 20 minutes or shorter, more preferably for 1 second or longer and 1 minute or shorter.

When the laminate can be rapidly heated to a predetermined diffusion temperature at a temperature increase rate of 25° C./second or higher, the diffusion time (holding time of the diffusion temperature) may be 30 seconds or shorter, 10 seconds or shorter, 5 seconds or shorter, 3 seconds or shorter, 2 seconds or shorter, or a very short time such as less than 1 second. The lower limit of the diffusion time is not particularly limited as long as the impurity diffusion component can be diffused to a desired degree. For example, the lower limit of the diffusion time may be 0.05 second or longer, 0.1 second or longer, 0.2 second or longer, 0.3 second or longer, or 0.5 second or longer. In this case, in a shallow region of the surface of the semiconductor substrate, the impurity diffusion component (A) is easily diffused at a high concentration.

In the diffusion step, an atmosphere around the laminate when the laminate is heated is preferably an atmosphere in which the concentration of oxygen is 1% by volume or lower. The concentration of oxygen in the atmosphere is more preferably 0.5% by volume or lower, even more preferably 0.3% by volume or lower, particularly preferably 0.1% by volume or lower. Most preferably, the atmosphere does not contain oxygen. The concentration of oxygen in the atmosphere is adjusted to a desired concentration at arbitrary timing in the step preceding the diffusion step. A method for adjusting the concentration of oxygen is not particularly limited. As the method for adjusting the concentration of oxygen, a method of passing an inert gas such as nitrogen gas into a device for heating the semiconductor substrate and discharging oxygen within the device to the outside of the device together with the inert gas is mentioned. In this method, the time during which the inert gas is passed is adjusted, and thus it is possible to adjust the concentration of oxygen within the device. As the time during which the inert gas is passed is increased, the concentration of oxygen within the device is lowered. When the diffusion is performed in an atmosphere of a low oxygen concentration, it can be considered that silicon oxide to be formed by oxygen on the surface of the diffusion-undergoing semiconductor substrate is unlikely to be formed. Consequently, the impurity diffusion component (A) is easily diffused into the substrate which is mainly formed of silicon, and thus the in-plane uniformity of diffusion of the impurity diffusion component (A) is enhanced.

When heated during the diffusion step, as illustrated in FIG. 2, the amine compound (B1), the amine compound residue (B2), and the like volatilize, and the impurity diffusion component (A) undergoes dehydration condensation or other reactions, so that an impurity diffusion component reaction layer 7 derived from the impurity diffusion component (A) is formed on the surface of the diffusion-undergoing semiconductor substrate 2, and the impurity diffusion component (A) diffuses into the diffusion-undergoing semiconductor substrate 2. Thereby, a semiconductor substrate 6 with the impurity diffusion component (A) diffused is manufactured. FIG. 2 is a schematic drawing illustrating an example of a method for manufacturing a semiconductor substrate using a laminate.

After the diffusion step described above, on the surface of the semiconductor substrate into which the impurity diffusion component (A) is diffused and in the vicinity of the surface, a residue (impurity diffusion component reaction layer) derived from the impurity diffusion component (A) may adheres, or a high-concentration layer which includes the impurity diffusion component at an extremely high concentration may be formed. The adherence of residue and the formation of the high-concentration layer may adversely affect the function of a semiconductor device when the semiconductor device is manufactured with the semiconductor substrate obtained through the diffusion step. Hence, after the diffusion step, processing for removing the residue and the high-concentration layer is preferably performed.

As the preferred processing after the diffusion step, processing which brings a hydrofluoric acid (HF) aqueous solution into contact with the surface of the semiconductor substrate is mentioned. In the processing described above, residue adhering to the surface of the semiconductor substrate can be removed. The concentration of the hydrofluoric acid aqueous solution is not particularly limited as long as residue can be removed. For example, the concentration of the hydrofluoric acid aqueous solution is preferably 0.05% by mass or higher and 5% by mass or lower, more preferably 0.1% by mass or higher and 1% by mass or lower. The temperature at which the hydrofluoric acid aqueous solution is brought into contact with the surface of the semiconductor substrate is not particularly limited as long as residue can be removed. For example, the temperature at which the hydrofluoric acid aqueous solution is brought into contact with the surface of the semiconductor substrate is preferably 20° C. or higher and 40° C. or lower, more preferably 23° C. or higher and 30° C. or lower. The time during which the hydrofluoric acid aqueous solution is brought into contact with the surface of the semiconductor substrate is not particularly limited as long as residue can be removed and unacceptable damage is prevented from being produced in the semiconductor substrate. For example, the time during which the hydrofluoric acid aqueous solution is brought into contact with the surface of the semiconductor substrate is preferably 15 seconds or longer and 5 minutes or shorter, more preferably 30 seconds or longer and 1 minute or shorter.

Before brought into contact with the hydrofluoric acid aqueous solution, the surface of the semiconductor substrate is preferably subjected to plasma ashing. In the processing described above, not only reside but also the high-concentration layer formed on the surface of the semiconductor substrate or in the vicinity of the surface of the semiconductor substrate can be removed. As the plasma ashing, plasma ashing using an oxygen-containing gas is preferable, and oxygen plasma ashing is more preferable. As long as the object of the present invention is not inhibited, various gases which are conventionally used in plasma processing together with oxygen can be mixed with the gas which is used for generation of oxygen plasma. Examples of the gas described above include nitrogen gas, hydrogen gas, and the like. The conditions of the plasma ashing are not particularly limited as long as the object of the present invention is not inhibited.

The semiconductor substrate obtained by the method described above makes it possible to sufficiently diffuse the impurity diffusion component into the semiconductor substrate, and also suppress generation of foreign matters because of excellent film formability. The obtained semiconductor substrate can be suitably applied to the manufacturing of a CMOS element for a CMOS image sensor and a semiconductor element such as a logic LSI device.

### EXAMPLES

Although the present invention will be more specifically described below using Examples, the present invention is not limited to Examples below.

### Examples 1 to 7, and Comparative Examples 1 to 7

### Manufacture of Laminate

As the impurity diffusion component (A) (component (A)), A1 below was used.

A1: boric acid

As the amine compound (B1) (component (B)), B1-1 to B1-5 below were used. As the amine compound (component (B‘)) which did not correspond to the amine compound (B1), B1’-1 to B1′-3 below were used.
B1-1: N,N′-bis(3-aminopropyl) ethylenediamine (molecular weight: 174.29)
B1-2: 1,3-propanediamine (molecular weight: 74.13)
B1-3: 3,3′-diaminodipropylamine (molecular weight: 131.22)
B1-4: N,N′-di-tert-butylethylenediamine (molecular weight: 172.32)
B1-5: N,N′-dimethylethylenediamine (molecular weight: 88.15)
B1′-1: tert-butylamine (molecular weight: 73.14)
B1′-2: diethylamine (molecular weight: 71)
B1′-3: triethylamine (molecular weight: 101.19)

The impurity diffusion components (A) of types listed in Table 1 were dissolved in propylene glycol monomethyl ether so as to respectively have concentrations listed in Table 1 to prepare impurity diffusion component-containing compositions for use in each of Examples and Comparative Examples.

The amine compounds saving as the amine compound (B1) or (B‘) component of types listed in Table 1 were dissolved in propylene glycol monomethyl ether so as to respectively have concentrations listed in Table 1 to prepare amine compound-containing compositions for use in each of Examples and Comparative Examples. A ratio of a number of moles of the impurity diffusion component (A) in the impurity diffusion component-containing composition to a number of moles of the amine compound (B1) in the amine compound-containing composition ((number of moles of the impurity diffusion component in the impurity diffusion component-containing composition)/(number of moles of the amine compound (B1) in the amine compound-containing composition)) is presented in column “component (A)/component (B) or (B’) (molar ratio)” of Table 1.

A silicon substrate (6 inches, n-type) including a flat surface was immersed in a 0.5% by mass-diluted hydrofluoric acid (DHF) at room temperature for 60 seconds, so as to remove a natural oxide film on the surface. With a spin coater, the amine compound-containing composition was applied on the surface of the silicon substrate from which the natural oxide film had been removed, so as to form a coating film. As film formation conditions, conditions of the spin coater were set to 2000 rpm and 60 seconds. After the application, the silicon substrate was dried at 100° C. for 60 seconds. Subsequently, with a spin coater, the impurity diffusion component-containing composition was applied on the surface of the coating film formed from the amine compound-containing composition on the silicon substrate, so as to form a coating film. As film formation conditions, conditions of the spin coater were set to 2000 rpm and 60 seconds. After the application, the silicon substrate was dried at 100° C. for 60 seconds. For the coating film after the drying, an average value of film thicknesses of five points measured with an ellipsometer is presented in column “Film thickness” of Table 1. Note that the film thickness of this coating film refers to a total film thickness of the amine compound layer 3 and the impurity diffusion component layer 4. Thereby, a laminate was obtained. In Comparative Example 1, the amine compound-containing composition was not applied but the impurity diffusion component-containing composition was applied, and in Comparative Example 2, the amine compound-containing composition was applied but the impurity diffusion component-containing composition was not applied.

### Evaluation of Film Formability

For the obtained laminate, the surface of the coating film was observed under a microscope (100x). A case that a film having a thickness of 0.5 nm or more could be formed and no foreign matters were observed was evaluated as “good” (indicated by circle symbol (o)). A case that a film having a thickness of 0.5 nm or more could not be formed was evaluated as “a”. A case that foreign matters were observed and a uniform film could not be formed was evaluated as “b”. The results are presented in Table 1.

### Manufacture of Semiconductor Substrate Diffusion

With a rapid thermal anneal device (lamp anneal device), under a nitrogen atmosphere at a flow rate of 1L/m, at a temperature increase rate of 25° C./second, the obtained laminate was heated to 1050° C., the temperature was held for 10 seconds, and the diffusion processing was performed. The starting point of the diffusion time (10 seconds) was the time when the temperature of the substrate reached 1050° C. After the completion of the diffusion, the semiconductor substrate was rapidly cooled to room temperature. The cooled semiconductor substrate was immersed in 0.5% by mass-diluted hydrofluoric acid (DHF) at room temperature for 30 seconds, so as to remove surface deposits.

### Evaluation of Diffusion Property

A sheet resistance value Rs (Ω/sq.) of the cooled semiconductor substrate was measured. The results are presented in Table 1. In column “P/N”, a case that the silicon substrate is inverted from n-type to p-type before and after the diffusion is represented by “N→P”, and the case that the silicon substrate remains in n-type is represented by “N→N”.

### Examples 8 to 10

### Manufacture of Laminate

As the impurity diffusion component (A) (component (A)), the above A1 was used.

As reactive amine compound (component (B)) that provides the amine compound residue (B2), B2-1 to B2-3 below were used. B2-1: 3-aminopropyltrimethoxysilane (APTMS) (molecular weight: 179.3) B2-2: N-2-(aminoethyl)-3-aminopropyltrimethoxysilane (AEAPTMS) (molecular weight: 222.4) B2-3: 3-[2-(2-(aminoethylaminoethylamino)propyl] trimethoxysilane (AEAEAPTMS) (molecular weight: 265.4)

The impurity diffusion components (A) of types listed in Table 1 were dissolved in a mixed solution of propylene glycol monomethyl ether:propylene glycol monomethyl ether acetate (3:7) so as to respectively have concentrations listed in Table 1 to prepare impurity diffusion component-containing compositions for use in each of Examples and Comparative Examples.

The reactive amine compounds that provide amine compound residues (B2) of types listed in Table 1 were dissolved in water so as to respectively have concentrations listed in Table 1 to prepare amine compound-containing compositions for use in each of Examples and Comparative Examples. A ratio of a number of moles of the impurity diffusion component (A) in the impurity diffusion component-containing composition to a number of moles of the reactive amine compound that provides the amine compound residue (B2) in the amine compound-containing composition ((number of moles of the impurity diffusion component (A) in the impurity diffusion component-containing composition)/(number of moles of the reactive amine compound that provides the amine compound residue (B2) in the amine compound-containing composition)) is presented in column “component (A)/component (B) or (B′) (molar ratio)” of Table 1.

A silicon substrate (6 inches, n-type) including a flat surface was immersed in a 0.5% by mass-diluted hydrofluoric acid (DHF) at room temperature for 30 seconds, so as to remove a natural oxide film on the surface. The silicon substrate from which the natural oxide film had been removed was washed with ion-exchanged water, then immersed in the amine compound-containing composition at room temperature for 60 seconds, and washed with ion-exchanged water. Subsequently, with a spin coater, the impurity diffusion component-containing composition was applied on the surface of the coating film formed from the amine compound-containing composition on the silicon substrate, so as to form a coating film. As film formation conditions, conditions of the spin coater were set to 2000 rpm and 60 seconds. After the application, the silicon substrate was dried at 100° C. for 60 seconds. For the coating film after the drying, an average value of film thicknesses of five points measured with an ellipsometer is presented in column “Film thickness” of Table 1. Note that the film thickness of this coating film refers to a total film thickness of the amine compound layer 3 and the impurity diffusion component layer 4. Thereby, a laminate was obtained.

The obtained laminate was evaluated for film formability, semiconductor substrate production, and diffusion properties in the same manner as in Example 1. The results are presented in Table 1.

### Examples 11 to 12 and Comparative Examples 8 to 9

### Manufacture of Laminate

As the impurity diffusion component (A) (component (A)), A2 below was used.

A2: phosphoric acid

As the amine compound (B1) (component (B)), the above B1-1 was used.

The impurity diffusion components (A) of types listed in Table 1 were dissolved in propylene glycol monomethyl ether so as to respectively have concentrations listed in Table 1 to prepare impurity diffusion component-containing compositions for use in each of Examples and Comparative Examples.

The amine compounds (B1) of types listed in Table 1 were dissolved in propylene glycol monomethyl ether so as to respectively have concentrations listed in Table 1 to prepare amine compound-containing compositions for use in each of Examples. A ratio of a number of moles of the impurity diffusion component (A) in the impurity diffusion component-containing composition to a number of moles of the amine compound (B1) in the amine compound-containing composition ((number of moles of the impurity diffusion component (A) in the impurity diffusion component-containing composition)/(number of moles of the amine compound (B1) in the amine compound-containing composition)) is presented in column “component (A)/component (B) or (B′) (molar ratio)” of Table 1.

A silicon substrate (6 inches, p-type) including a flat surface was immersed in a 0.5% by mass-diluted hydrofluoric acid (DHF) at room temperature for 60 seconds, so as to remove a natural oxide film on the surface. With a spin coater, the amine compound-containing composition was applied on the surface of the silicon substrate from which a natural oxide film had been removed, so as to form a coating film. As film formation conditions, conditions of the spin coater were set to 2000 rpm and 60 seconds. After the application, the silicon substrate was dried at 100° C. for 60 seconds. Subsequently, with a spin coater, the impurity diffusion component-containing composition was applied on the surface of the coating film formed from the amine compound-containing composition on the silicon substrate, so as to form a coating film. As film formation conditions, conditions of the spin coater were set to 2000 rpm and 60 seconds. After the application, the silicon substrate was dried at 100° C. for 60 seconds. For the coating film after the drying, an average value of film thicknesses of five points measured with an ellipsometer is presented in column “Film thickness” of Table 1. Note that the film thickness of this coating film refers to a total film thickness of the amine compound layer 3 and the impurity diffusion component layer 4. Thereby, a laminate was obtained. In Comparative Examples 8 and 9, the amine compound-containing composition was not applied but the impurity diffusion component-containing composition was applied.

The obtained laminate was evaluated for film formability, semiconductor substrate production, and diffusion properties in the same manner as in Example 1. The results are presented in Table 1. A case that the silicon substrate is inverted from p-type to n-type is represented by “P→N”.

Table 1

| | Component (A) | Component (B) or (B′) | | | | Component (A)/ Component (B) or (B′) (molar ratio) | Film thickness (nm) | Diffusion property | | Film formability |
|---|---|---|---|---|---|---|---|---|---|---|
| | Type/ Concentration (% by mass) | Type/ Concentration (% by mass) | Number of C atoms | Number of N atoms | Grade | | | Rs (Ω/sq. ) | P/N | |
| Example 1 | A1/0.08 | B1-⅟0.04 | 8 | 4 | 2,1 | 5.6 | 1.7 | 1215.9 | N → P | o |
| Example 2 | | B1-2/0.017 | 3 | 2 | 1 | 5.6 | 0.8 | 735.5 | N → N | o |
| Example 3 | | B1-2/0.17 | 3 | 2 | 1 | 0.56 | 0.8 | 2132.1 | N → P | o |
| Example 4 | | B1-3/0.030 | 6 | 3 | 1, 2 | 5.6 | 1.9 | 3342.1 | N → P | o |
| Example 5 | | B1-3/0.300 | 6 | 3 | 1, 2 | 0.56 | 2.1 | 3085.1 | N → P | o |
| Example 6 | | B1-4/0.020 | 10 | 2 | 2 | 5.6 | 0.8 | 766.6 | N → N | o |
| Example 7 | | B1-5/0.020 | 4 | 2 | 2 | 5.6 | 0.6 | 462.2 | N → N | o |
| Example 8 | | B2-1/1.00 | 3 | 1 | 1 | 21.6 | 2.0 | 4142.4 | N → P | o |
| Example 9 | | B2-2/1.24 | 5 | 2 | 1, 2 | 21.6 | 2.0 | 4260.4 | N → P | o |
| Example 10 | | B2-3/1.48 | 7 | 3 | 1, 2 | 21.6 | 1.9 | 3954.2 | N → P | o |
| Example 11 | A2/0.063 | B1-⅟0.04 | 8 | 4 | 2,1 | 5.6 | 4.1 | 260.4 | P → N | o |
| Example 12 | A2/0.63 | | 8 | 4 | 2,1 | 5.6 | 18.7 | 94.9 | P → N | o |
| Comparative Example 1 | A1/0.08 | None | | | | | 0.1 | 237.6 | N → N | a |
| Comparative Example 2 | None | B1-⅟0.04 | 8 | 4 | 2, 1 | | 1.5 | 213.9 | N → N | o |
| Comparative Example 3 | A1/0.08 | B1′-⅟0.017 | 4 | 1 | 1 | 5.6 | 0.3 | 252.1 | N → N | a |
| Comparative Example 4 | | B1′-⅟0.170 | 4 | 1 | 1 | 0.56 | 0.6 | 253.7 | N → N | o |
| Comparative Example 5 | | B1′-2/0.167 | 4 | 1 | 2 | 5.6 | 0.3 | 275.4 | N → N | a |
| Comparative Example 6 | | B1′-3/0.023 | 3 | 1 | 3 | 5.6 | 0.3 | 235.4 | N → N | a |
| Comparative Example 7 | | B1′-3/0.232 | 3 | 1 | 3 | 0.56 | 0.4 | 236.7 | N → N | a |
| Comparative Example 8 | A2/0.063 | None | | | | | 2.3 | 527.7 | P → N | b |
| Comparative Example 9 | A2/0.63 | | | | | | Unmeasurable | 117.0 | P → N | b |

Table 1 shows that the impurity diffusion component could be sufficiently diffused by the laminates of Examples 1 to 12 having the amine compound layer and the impurity diffusion component layer in this order on the diffusion-undergoing semiconductor substrate, the laminates having been formed by applying the amine compound-containing composition including the amine compound (B1) or the reactive amine compound that provides the amine compound residue (B2), and the impurity diffusion component-containing composition including the impurity diffusion component (A) in this order on the diffusion-undergoing semiconductor substrate. Also, it can be seen that the laminates of Examples 1 to 12 had good film formability. In addition, there was a tendency that, as the amount of the amine compound (B1) increased, the diffusion property was further improved.

On the other hand, it can be seen that the impurity diffusion component was not sufficiently diffused in Comparative Example 1 in which boric acid was used as the impurity diffusion component (A) and the amine compound-containing composition including the amine compound (B1) or the reactive amine compound that provides the amine compound residue (B2) was not applied, Comparative Example 2 in which the impurity diffusion component-containing composition including the impurity diffusion component (A) was not applied, and Comparative Examples 3 to 7 in which an amine compound other than the amine compound (B1) or the reactive amine compound that provides the amine compound residue (B2) was used, compared to Examples 1 to 12. Also, it can be seen that foreign matters were observed and the film formability was poor in Comparative Examples 8 and 9 in which phosphoric acid was used as the impurity diffusion component (A) and the amine compound-containing composition including the amine compound (B1) or the reactive amine compound that provides the amine compound residue (B2) was not applied.

### EXPLANATION OF REFERENCE NUMERALS

1 Laminate
2 Diffusion-undergoing semiconductor substrate
3 Amine compound layer
4 Impurity diffusion component layer
5 Second amine compound layer

1. A laminate for use in diffusion of an impurity diffusion component (A) into a semiconductor substrate, the laminate comprising:
a diffusion-undergoing semiconductor substrate, an amine compound layer, and an impurity diffusion component layer,
wherein the amine compound layer is in contact with one main surface of the diffusion-undergoing semiconductor substrate,
the impurity diffusion component layer is in contact with a main surface of the amine compound layer, wherein the main surface does not contact the diffusion-undergoing semiconductor substrate, and
wherein the amine compound layer comprises an amine compound (B1) including two or more nitrogen atoms and having an amino group constituted by at least one of the two or more nitrogen atoms; and/or an amine compound residue (B2) having one or more amino groups that bind to the main surface via a covalent bond.

2. The laminate according to claim 1, wherein the amine compound (B 1) or a reactive amine compound that provides the amine compound residue (B2) comprises a linear or branched aliphatic amine compound.

3. The laminate according to claim 1, wherein the amine compound (B1) or the reactive amine compound that provides the amine compound residue (B2) comprises an amine having four or more amino groups.

4. The laminate according to claim 1, wherein the impurity diffusion component (A) comprises at least one selected fromthe group consisting of a boron compound, a phosphorus compound, and an arsenic compound.

5. A method for manufacturing the laminate according to claim 1, the method comprising:
applying, on the diffusion-undergoing semiconductor substrate, an amine compound-containing composition comprising the amine compound (B1) or a reactive amine compound that provides the amine compound residue (B2); and
applying an impurity diffusion component-containing composition comprising the impurity diffusion component (A) after applying the amine compound-containing composition.

6. A method for manufacturing a semiconductor substrate, the method comprising diffusing the impurity diffusion component (A) into the diffusion-undergoing semiconductor substrate by heating the laminate according to claim 1.
